(19) United States
(12) Patent Application Publication
(10) Pub. No.: US 2006/0274826 A1
(43) Pub. Date: Dec. 7, 2006

(54) Binary rate multiplier configured to generate accurate coefficients

(75) Inventor: Andrew Martin Mallinson, Kelowna (CA)

Correspondence Address: STEVENS LAW GROUP, P.O. BOX 1667, SAN JOSE, CA, 95109, US

(73) Assignee: ESS Technology, Inc., Fremont, CA (US)

(21) Appl. No.: 11/444,574

(22) Filed: May 31, 2006

Related U.S. Application Data
(60) Provisional application No. 60/686,115, filed on May 31, 2005.

(51) Int. Cl. H03H 7/30

(52) U.S. Cl. 375/229

(57) ABSTRACT

A system and method are provided for generating accurate coefficients in a binary rate multiplier by signaling an enabling circuit to generate an enabling signal to the binary rate multiplier such that the average effect of the factored output signal corresponds to a signal multiplied by a predetermined coefficient value; where the system multiplies a signal by a plurality of factors in response to the enabling signal, where the smallest exponent of two is determined that is greater than the factor desired; and the desired factor is divided by the smallest exponent to generate a resulting fraction that is the duty cycle of the enabling signal.

### BACKGROUND

The invention is directed to a binary rate multiplier configured to generate accurate coefficients, and can be implemented in an analog to digital converter, a digital to analog converter, a sigma delta modulator or other circuit where the generation of accurate coefficients of multiplication are desired. The need to generate accurate coefficients of multiplication arises in an electronic device such as a digital filter. A Binary Rate Multiplier in the context of this discussion is a device which accepts a clock input and generates a signal output—that signal output having an average rate that differs from the input clock rate by a factor as set on a second controlling input to the device.

An electronic filter is designed to transmit some range of signal frequencies while rejecting others, i.e., to emphasize or “pass” certain frequencies and attenuate or “stop” others. An electronic filter may be implemented in the analog domain, or in the digital domain. In the digital domain an electronic filter operates on a succession of discrete samples of the input. A digital filter has two types depending on whether the impulse response contains a finite or potentially infinite number of nonzero terms. A finite impulse response (FIR) filter is necessarily linear phase, a characteristic that ensures that a filter has a constant group delay independent of frequency. An infinite impulse response digital filter requires much less computation to implement than a FIR filter with a corresponding frequency response. However, IIR filters cannot generally achieve an adequate linear-phase response and are more susceptible to finite word length effects, which may result in round-off noise, coefficient quantization error and overflow oscillations. In addition, FIR filters require more bit width, up to 50 bits in practice, which can be burdensome to a circuit. “Bit width” refers to the width of the bits that must be processed in parallel and is the “data path width” of the digital implementation.

In the design of a digital filter it is necessary to implement a multiplying element. In operation, an element that accepts as input a certain digital number and creates as output a second digital number representing a scaled version of that input. It therefore multiplies the input number by a factor. It is well known how to construct such a digital multiplier. For example, in the general case when the multiplicand can be any number, a significant amount of logic resource or time must be expended on the multiplier since all the bits within the multiplicand contribute to the output. Certain values of multiplicand may allow simplification: when only one bit is non-zero in the representation of the multiplicand a single shift operation suffices to complete the multiplication. For example, multiplication by 4 is simply a left shift of two binary places. A digital filter necessarily consists of a number of digital multiplication operations, and it is known that a better filter, that is, one achieving a higher degree of unwanted signal rejection, may be constructed if the values of the multiplicands in the digital filter are precisely set, having an exact value and hence needing a wider binary word to represent them. Therefore a compromise is necessary, where the better quality filter will require more resources in the multiplier element since that multiplier element is operating with a wide and precisely set multiplicand.

Therefore, there exists a need for a filter that has an improved accuracy, but that requires less bit width, and thus uses less resources. As will be seen, the invention provides this in an elegant manner.

### BRIEF DESCRIPTION OF THE DRAWINGS

FIG. 1 is a diagrammatic view of a digital filter configured according to the invention;

FIG. 2 is a diagrammatic view of a sigma delta multiplier of FIG. 1; and

FIG. 3 is a flow diagram of an operation of the digital filter according to the invention.

### DETAILED DESCRIPTION

A system and method are provided for generating accurate coefficients in a binary rate multiplier by signaling an enabling circuit to generate an enabling signal to the binary rate multiplier such that the average effect of the factored output signal corresponds to a signal multiplied by a predetermined coefficient value; where the system multiplies a signal by a plurality of factors in response to the enabling signal, where the smallest exponent of two is determined that is greater than the factor desired; and the desired factor is divided by the smallest exponent to generate a resulting fraction that is the duty cycle of the enabling signal.

The invention is directed to a system and method for performing digital multiplication and filtering. The invention provides a digital filter having a binary rate multiplier for generating accurate coefficients by multiplying a signal by a plurality of factors in response to an enabling signal, and an enabling circuit configured to enable and disable the binary rate multiplier in response to an auxiliary input such that the average effect of the factored output signal corresponds to a signal multiplied by a predetermined coefficient value. The enabling circuit may be configured to enable and disable the binary rate multiplier in response to one auxiliary input added to a factored input signal added to another auxiliary input added to a factored feedback signal from the binary multiplier. The enabling circuit would have a duty cycle such that, over a finite period of cycles, the effective factor of multiplication output to the binary rate multiplier differs from the first factor. Also, the enabling circuit may be configured to receive an input signal that is multiplied by one factor to generate a factored input that is logically ANDed with a first auxiliary input, and also configured to receive a feedback input that is multiplied by another factor to generate factored feedback signal that is added to a second auxiliary input, wherein the ANDed results are then combined to generate an enabling signal to be transmitted to the binary rate multiplier that correspond to a simple shift of bits such that each factor is a power of two. In operation, the multiplier with the associated enabling signal operates at a rate outside the frequency band passed by the filter, the artifacts of the enabling signal therefore being suppressed by the action of the filter. Two or more digital filters may operate concurrently, as may be desirable to process multiple signals simultaneously in for example, a multi-channel audio system, wherein the means to generate the duty cycle used as the enabling signal is shared between two or more multipliers of the multiple filters. In such a configuration, the multipliers may operate in a cascading manner such that the output is the compound response of two or more filters in succession, as may be desirable for a more effective filter, wherein the duty cycle used as the enabling signal is shared between two or more multipliers of the compound filter.

The invention provides a system and method of filtering that operates with a novel form of multiplier. The multiplier has the desirable feature of a wide and accurately set multiplicand, but requires fewer resources than conventional multiplier architectures. The filter runs at a clock rate that is significantly higher than the bandwidth of the filter. For example, the rate of operation of this filter may be 10 MHz (10 million operations per second and an input digital data rate of 10 million samples per second) and the filter action be a low pass filter at 50 Khz. In this case the filter is passing only a small fraction of the signal bandwidth that could be represented in a 10 Mhz data rate: the maximum signal frequency that could be present is 5 Mhz and the pass band is the first 50 Khz of this signal.

The operation of this novel multiplier exploits the fact that it is embedded in such a filter. The multiplier deviates from the ideal performance of a multiplier and so creates artifacts. However, these artifacts are only present in the band that the filter rejects. Therefore, in all frequency bands of interest, the multiplier performs as well as known multipliers but uses fewer resources. The artifacts created by the novel multiplier are rejected by the action of the filter, of which it is a constituent part, and the artifacts are not present in the output. Furthermore, according to the invention, the multiplier has certain resources which, in a multiple-channel implementation need not be duplicated. That is, in cases where instantiation of more than one concurrent filter is desirable, these resources may be shared, further reducing the aggregate resources required.

Again, a digital filter necessarily consists of a number of digital multiplication operations. In conventional practice, it is known that a filter that that is capable of achieving a high degree of unwanted signal rejection may be constructed if the values of the multiplicands in the digital filter are precisely set at an exact value. Thus, a wider binary word would be necessary to represent the multiplicands. Thus, the better filter will require more resources in the multiplier element since that multiplier element is operating with the larger multiplicand that requires more bits. A circuit configured according to the invention provides accurate coefficients, and does not require a large word to define the multiplicand needed.

The invention provides a means to improve upon any digital filter by allowing the divisible operations of the embedded multiplier in such a filter to be simply “shift and add” operations. In conventional systems, high performance digital filters require coefficient values that have high resolution, for example, 2.34567 or 1.96543. Such coefficients require significant logic resources to implement, typically digital multipliers or the equivalent thereof. The invention enables digital filters that have simple “power of 2 coefficients” (ie 2, 4, 64, ½, ¼, etc) in the associated multipliers to operate at the same level of performance as a filter that has more complex multipliers. Thus, simple and inexpensive shift and add operations are required to get the same result as more complicated and expensive filters having high resolution coefficients. A binary rate multiplier generates an “enabling signal” to the sections of the digital filter such that operation may be prevented or enabled under control of this enabling signal. The duty cycle of this enabling signal is adjusted such that the average operation of the simple power of two filter stage corresponds to the same operation of a more complicated filter with high resolution coefficient.

For example, if the ideal coefficient is, for example 3.2, the filter is operated with a coefficient value of 4, but operation is prevented on every 5^{th} clock thus implementing an average multiplication by 3.2. That is, multiplying by 4, 4, 4, 4, 0 is equivalent, over a time average value, to multiplying by 3.2, 3.2, 3.2, 3.2, 3.2. The manner in which the system chooses which operation or how many operations are prevented to accomplish the correct math is as follows. First, the smallest power of 2 is found that is greater than the factor required. Then, the desired factor is divided by this number. The resulting fraction is the duty cycle of the enabling signal. For example, in the case where it is desired to multiply by 3.2, the process is configured to Find 4 (the smallest power of 2 greater than 3.2) and divide 3.2/4=4/5. Therefore, the enabling signal must be active for 4 out of every 5 cycles of the clock.

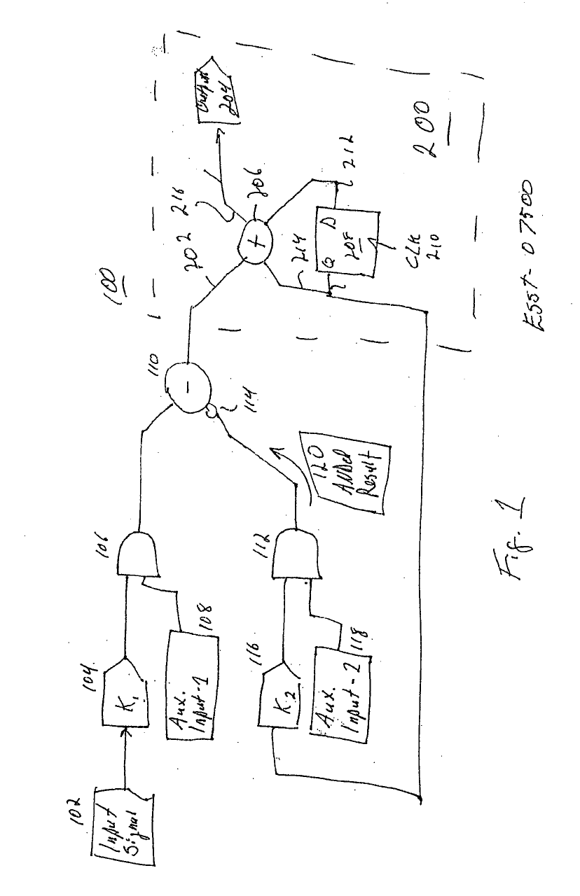

Referring to FIG. 1A, one embodiment of the invention is illustrated. In one embodiment, the invention provides a single pole filter with arbitrary coefficients of input and feedback. The description “single pole filter” is used because the transfer characteristic of the filter is described by an equation as follows. Using Y as the quantity in the integrator and presented on the wire labeled 204 and X as the signal input quantity 102, then
dY/dt=K1*F1*X−K2*F2*Y
where the factors K1 and K2 are from the shifter elements 104 and 115 respectively. The factors F1 and F2 are introduced to show that the coefficients need not be powers of 2 as they would be if only the shifters were used. The factors F1 and F2 and their generation are the subject of this disclosure). Using ‘s’ as the Laplace operator, then
sY=K1*F1*X−K2*F2*Y
which may be expressed as
Y=X.K1*F1/(s+K2.F2).
This is then why the filter is called a single pole filter, there is a single term of the form (s+a) in the denominator of the transfer function. This equation is developed in more detail below.

The single pole filter includes a first shifter 104 configured to multiply the input 102 by a first factor K₁, that factor being constrained to a simple power of 2, and a first AND gate 106 configured to receive the shifter output and an auxiliary input 108 as inputs. A second shifter 116 is configured to multiply a feedback input by a second factor K₂, and a second AND gate 112 is configured to receive an output from the second shifter and a second auxiliary input 118. A logic subtractor 110 is configured to subtract the output of the second AND gate from the output of the first AND gate. An integrator 200 made up of an adder and a register is configured to receive an output from the logic subtractor and generate the feedback output to be multiplied by the second shifter 116 via a feedback loop. Those skilled in the art will understand that the elements 106,108,112 and 118 do not occur in the prior art. Operation of the single pole filter without the use of 106,108,112 and 118 is known.

The operation of this single pole filter embodiment may be understood by reference to the descriptive equation: the output parameter Y (the bus 214 on the output of the register in the accumulator) is a sequence of values. Each value is determined from the previous value as Yₙ₊₁=(Cᵢₙ·In)−(C_{fb}·Yₙ)+Yₙ. Consequently, Cᵢₙ, C_{fb} are the multiplication terms of the input and current output respectively. The invention provides a means to break up Cᵢₙ, C_{fb} into two parts such as Cᵢₙ=Kᵢₙ·Bᵢₙ where Kᵢₙ is a power of two shift, and Bᵢₙ is a binary signal (i.e. either 0 or 1) having a duty cycle between 0.5 and 1 derived from a Binary Rate Multiplier. Multiplication by K is then a simple shift, multiplication. by B is accomplished by enabling or disabling the output of the K shifter. The disabling of output is conveniently done by forcing the shifter output to all zeros, as may be done with a series of AND gates on each bit of the shifter output, the second input being commonly connected to a control input. If the control input is “1”, the AND gates pass the signal on the bus unchanged. If the controlling input is “0”, each bit is forced to “0” and hence the bus represents “0”. Over a few cycles of the clock, the factor K will be applied each time, but the Binary Rate Multiplier signal B will, in general, have prevented the operation (i.e. forced the output to be zero) for one or more of the clock cycles. Therefore, the average multiplicand is not K but K.B—which is the desired quantity C.

In the FIG. 1 the shifter element notated as 104 (K1) is providing the term Kᵢₙ and the shifter element 116 (K2) is providing the term K_{fb} in the equations above. The presence of the AND gate 106 and auxiliary input 108 provide the means to enable or disable the multiplication by K and so element 106 and 108 provide the term Bᵢₙ in the equation above and finally elements 112 and 118 provide the term B_{fb} in the equation above.

The binary rate modulation method includes receiving an input signal in an initial input and multiplying the input by a factor with a combination of the shifter and the modulator. The method further consists of receiving the shifter output and a first auxiliary input into a first logic AND gate. Then the method receives an output from a feedback loop of a binary rate multiplier and a second auxiliary input with a second logic AND gate. The second AND input, once receive by the subtractor, is then subtracted from the first AND input. In this operation, the circuit first determines the smallest exponent of 2 that is greater than the factor desired. The circuit then divides the desired factor by the smallest exponent to generate a resulting fraction. This resulting fraction is the duty cycle of the enabling signal.

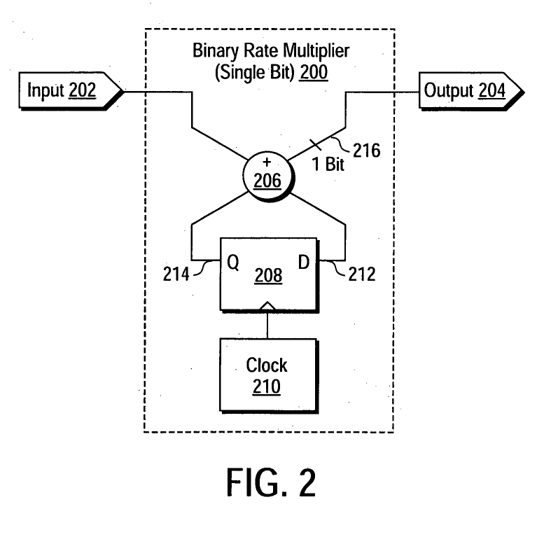

Referring now to FIG. 2, a first order modulo arithmetic sigma delta is illustrated. This is the BRM element that will generate the duty cycle that will enable or disable the operation of the simple “power of two” multiplier, such as the shifter. The BRM includes an input 202 for receiving an input signal and an output 204 for outputting a binary rate signal. The input signal is transmitted to a digital adder 206. The adder is connected to a flip flop 208, which is connected to a clock 210. The adder transmits an output signal to flip flop D input 212. The clock transmits a clock pulse of a predetermined frequency to enable the Q output bus 214 of the flip flop. The adder then adds the input signal to the signal received from the Q output bus 214 of the flip flop, and outputs a sum signal back to the D input 212 of the flip flop and a carry output 216 to the output 204.

The output wire 216 is the carry output of the adder. When the result exceeds that which can be represented in the bus width of the element 208, this output wire will be logic high. The result transmitted to the D-type 208 will be wrong, because it has failed to capture the “overflow” bit that is present in the carry output. However, the system is designed to operate in this manner. The fact that the output has overflowed into the carry signal 216 corresponds to the fact that the resulting number to the D-type 208 is mathematically the modulus of the “real” output number to some base. This is the meaning of the description “modulo arithmetic” and is used to indicate that the number is always within a finite range. Furthermore, the rate of occurrence of the overflow into the wire 206 is precisely controlled by the input quantity 202. If 202 were logic zero, no overflow would occur. This is because the input quantity 202 is increased in value at the rate of occurrence of overflow events, and it increases in proportion. Therefore the rate of output is controlled by the binary number present on the input quantity 202. This is the meaning of the description “Binary Rate Multiplier”, where the rate of the clock is multiplied by a factor due to the input number on 202 and creates an output rate on the carry output wire 206.

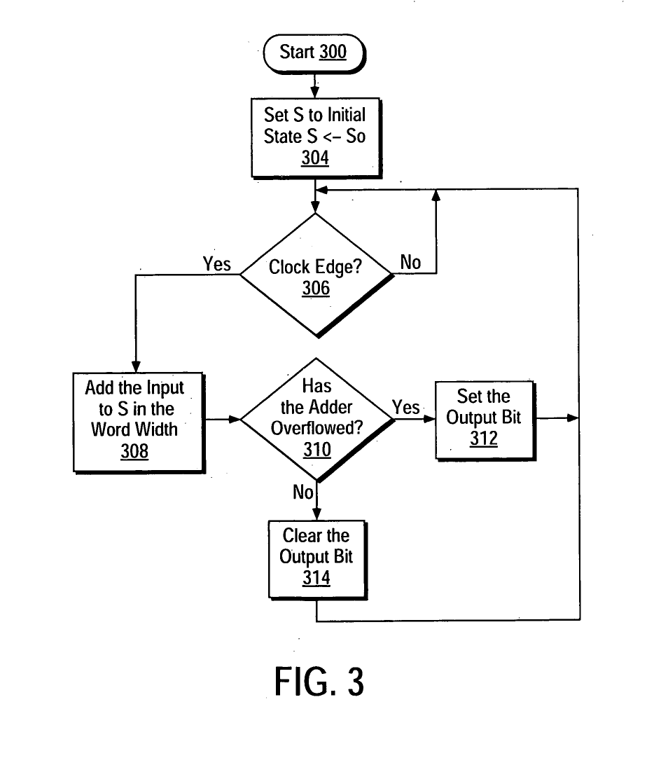

Referring to FIG. 3, a flow chart is shown illustrating the function of a single bit BRM implemented as a modulo arithmetic sigma delta modulator. The process 300 starts at step 302. The output S of the adder 206 (FIG. 2), is set to an initial state, S←S₀, in step 304. Then, step 306 queries whether a clock edge is present, where the clock edge triggers the addition function. If not present, it continues to wait in step 306. Once the clock edge is present, in step 308, the input signal is added to the output S of the adder 206, which is taken from the flip flop 210. In step 310, there is a query of whether the adder 206 has overflowed. If it has overflowed, in step 312, the output carry bit is set, and an output carry signal is transmitted to output 204. If the adder has not over flowed, then, instep 314, the carry output bit is cleared, and a carry bit is not transmitted to output 204. In either case, the process returns to step 306 and waits for the next clock edge before the adder resumes function.

In operation, if the bus width to the adder is eight bits, then the input N=128 (2⁷), causes the carry output to alternate bits (0, 1, 0, 1 . . . ). Thus, the density of the outputs is 50%. As N approaches 256, the density tends to 100%. As N approaches 0, the density tends to 0%. Thus, the BRM outputs at a rate that is proportional to the clock frequency and the input signal frequency, or f=(N/256) f_{clk}. Thus the input of the BRM creates the density of logical zero and logical one values at the output. The BRM generates a single bit signal that expresses a signal in the form of successive states of the BRM over time.

Referring again to FIG. 2, the operation of the BRM will be further described. The register with input 212 and output 214 is connected with adder 206. At each clock cycle, the register will present at the bus 214 the contents of bus 212. Bus 212 is connected to the adder output that generates a sum of the input signal and the output signal from the flip flop Q output 214. This output will assume the value that is the sum of the bus 214 and the input signal 202. If any overflow occurs in this addition process, a carry bit will be transmitted to output 204 via carry output 216.

For the purpose of illustration of the operation of a practical circuit, it can be assumed that the bus widths 214, 212 and 202 are all 8 bits wide. Initially; it is assumed that the register initially contains 0 and the input bus 202 contains the number 128. Thus flip flop input 212 also has the number 128 since it is adding 214 and (the register output) and 202 the register input. The carry output 204 is at this time not set (it is 0) since the sum of 128 and 0 does not overflow in an 8 bit word. Upon the next clock the bus 214 assumes the value of the bus 212, and hence 212 will now have to encode not 0+128 as before the clock, but 128+128=256, since 128 is now preset at the 214 bus. However, 256 cannot be encoded in an 8 bit word. Hence, the carry output 216 will be set and the bus 212 will in fact hold the residue of the sum modulo 256, thus it will encode 0. The time the carry output 204 is set, it is at logic 1.

Upon the next clock signal, the register output 214 assumes the value 0 that was preset on the 212 bus, thus the register output 214 is returned to the initial state and the carry output 204 is not set, it is logic 0. Subsequent pulses of the clock will result in the carry output generating the sequence 01010 . . . Therefore, by application of the number 128 on the bus 202, the sequence 010101 is generated on the carry output 204. If the input bus 202 were to encode the number 64, the sequence of carry outputs would be 000100010001 etc. Observing this operation, the circuit generates a rate of output carry signals to output 204 that is proportional to the number input signal received on the input bus 202. The device therefore operates as a binary rate multiplier, and the output rate is F_{clk}*/N/256, where F_{clk} is the rate of applied clock to the register and N is the number on the input bus 202.

As an aid to understanding, consider that the BRM device is creating a single bit, where the single bit produced is either logic high or logic low (or, a value of 1 or 0 respectively). However, the percentage time spent high or low is proportional to the input number. For example, it has been observed that, for an 8 bit device, 128 results in 010101, 64 results in 00010001, etc. The percentage time, known in the art as the duty cycle, is proportional to the input number. In a circuit designed according to the invention, the fact that the average value of the output bit is the signal of interest to be processed is exploited. However, because that signal has only 1 bit, it is easy to process it, as the logic required is small. The alternative would be to process the input word, in this case 8 bits.

This device illustrated in FIG. 2 has been described as a binary rate multiplier that generates as single bit output. This is similar in operation to a first order Sigma Delta (ΣΔ) Modulator. It can be characterized as a first order sigma delta modulator implemented as a modulo arithmetic device. A modulo arithmetic device is one where math operations are performed in a finite bus width and the expected overflow of the math operation is utilized as a part of the executed algorithm.

Therefore, the invention provides a system and method for combining the multiplier, which is implemented as a simple shifter, with an enabling signal generated by the method of BRM described. Over a period of time, the average value of a multiplicand in a filter is caused to consist of two parts: that part K that is a power of two, and that part B that is duty cycle derived by the method described. It may also be derived by any method known to result in a pre-determined duty cycle. The combination of these two factors results in a multiplication factor K.B, which is no longer constrained to be a power of two.

Given this description, those skilled in the art will note that the instantaneous value of the multiplicand on any given clock is either K (the power of 2) or 0. It is only over the time interval of the generation of the BRM signal that the average multiplicand is derived. The fact that the multiplicand is therefore time-varying and only having the desired value on average will, in the general case, cause the output signal processed by the filter to have artifacts, where artifacts are unwanted, spurious signals present in the output. However, upon further consideration, these spurious signals must be at a frequency higher that the time interval over which the BRM signal is generated, that is, it is known that over a sufficiently long time the average value is correct. Therefore, there is a lower limit on the frequency of any spurious signals. Therefore, if the filter is designed as a low pass filter, and if the lower limit of the spurious signal due to the time varying multiplicand is higher than the pass frequency of the low pass filter of which it is a part, then no spurious signals will be present at the output.

Also, the generation of the BRM signal may be done one time for use in multiple filters. As an example, consider the case of a stereo, or indeed six channel surround sound, audio filter. Here, the need arises to make two instances of a filter, or six instances in the case of a six channel system. Using this method, each filter will have its own version of the design shown in FIG. 1. The signal from the auxiliary elements notated. as for example, 108, will be identical in each instance of the filter. Therefore, the BRM method (or similar method), which is the auxiliary input 1, need only be instantiated one time, where its output signal is fed in parallel to each copy of the AND gate 106 present in each filter. Similarly, for the corresponding Aux Input 2 and for AND gate 116.

1. A digital filter comprising:
a binary rate multiplier for generating accurate coefficients by multiplying a signal by a plurality of factors in response to an enabling signal; and
an enabling circuit configured to enable and disable the binary rate multiplier in response to an auxiliary input such that the average effect of the factored output signal corresponds to a signal multiplied by a predetermined coefficient value.

2. A digital filter according to claim 1, wherein the enabling circuit is configured to enable and disable the binary rate multiplier in response to one auxiliary input added to a factored input signal.

3. A digital filter according to claim 1, wherein the enabling circuit is configured to enable and disable the binary rate multiplier in response to one auxiliary input added to a factored input signal and another auxiliary input added to a factored feedback signal from the binary multiplier.

4. A digital filter according to claim 1, wherein the enabling circuit is configured to enable and disable the binary rate multiplier in response to one auxiliary input added to a factored input signal added to another auxiliary input added to a factored feedback signal from the binary multiplier.

5. A digital filter according to claim 1, wherein the enabling circuit is configured to enable and disable the binary rate multiplier in response to one auxiliary input added to a factored input signal added to another auxiliary input added to a factored feedback signal from the binary multiplier, where the enabling circuit has a duty cycle such that, over a finite period of cycles, the effective factor of multiplication output to the binary rate multiplier differs from the first factor.

6. A digital filter as in claim 1, wherein the enabling circuit is configured to receive an input signal that is multiplied by one factor to generate a factored input that is logically ANDed with a first auxiliary input, and also configured to receive a feedback input that is multiplied by another factor to generate factored feedback signal that is added to a second auxiliary input, wherein the ANDed results are then combined to generate an enabling signal to be transmitted to the binary rate multiplier that correspond to a simple shift of bits such that each factor is a power of two.

7. A digital filter according to claim 6, wherein the enabling signal enables and disables the binary rate multiplier.
